(19) United States
(12) Patent Application Publication
(10) Pub. No.: US 2026/0293303 A1
(43) Pub. Date: Sep. 24, 2026

(54) GATE INTERCONNECT FOR SEQUENTIAL STAGGERED FIELD EFFECT TRANSISTORS

(71) Applicant: International Business Machines Corporation, Armonk, NY (US)

(72) Inventors: Thanh Nguyen, Troy, NY (US); Shay Reboh, Guilderland, NY (US); Eunsoo Cho, Albany, NY (US); Ruilong Xie, Niskayuna, NY (US); Utkarsh Bajpai, Suffern, NY (US); James Patrick Mazza, Saratoga Springs, NY (US)

(21) Appl. No.: 19/087,879

(22) Filed: Mar. 24, 2025

(51) Int. Cl. H10D 84/85; H01L 23/535; H10D 30/00; H10D 30/01; H10D 30/43; H10D 62/10; H10D 64/27; H10D 84/01

(52) U.S. Cl. CPC H10D 84/851; H10D 30/014; H10D 30/0191; H10D 30/43; H10D 30/502; H10D 62/121; H10D 64/518; H10D 84/0186; H10D 84/0188; H10W 20/20

(57) ABSTRACT

A gate merge connection assembly of a stacked field effect transistor (FET) device is provided. The gate merge connection assembly includes lower gate metal of a lower FET, upper gate metal of an upper FET and an L-shaped gate merge connection. The L-shaped gate merge connection includes a vertical section disposed in contact with the lower gate metal and extending upwardly through oxide vertically interposed between the lower and upper FETs and a horizontal section disposed in contact with the vertical section and extending horizontally to the upper gate metal.

### BACKGROUND

The present disclosure generally relates to fabrication methods and resulting structures for semiconductor devices. More specifically, the present disclosure relates to a gate interconnect for sequential staggered field effect transistors (FETs).

A transistor is a semiconductor device used to amplify or switch electrical signals and power and is one of the basic building blocks of modern electronics. An FET is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the present invention, a gate merge connection assembly of a stacked field effect transistor (FET) device is provided. The gate merge connection assembly includes lower gate metal of a lower FET, upper gate metal of an upper FET and an L-shaped gate merge connection. The L-shaped gate merge connection includes a vertical section disposed in contact with the lower gate metal and extending upwardly through oxide vertically interposed between the lower and upper FETs and a horizontal section disposed in contact with the vertical section and extending horizontally to the upper gate metal. Thus, the stacked FET device provides for connection of respective gate metals of each of the upper FET device and the lower FET device.

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and an L-shaped gate merge connection. The lower FET includes lower gate metal surrounding semiconductor channels and a self-aligned contact (SAC) cap disposed over the lower gate metal. The upper FET includes upper gate metal surrounding semiconductor channels. The L-shaped gate merge connection includes a vertical section disposed in contact with the lower gate metal and extending upwardly through the oxide and a horizontal section disposed in contact with the vertical section and extending horizontally to the upper gate metal. Thus, the stacked FET device provides for connection of respective gate metals of each of the upper FET device and the lower FET device.

According to an aspect of the present invention, a fabrication method of a stacked field effect transistor (FET) device with a lower FET and an upper FET structure in a staggered formation and with oxide vertically interposed between the lower FET and the upper FET structure is provided. The fabrication method includes executing deep gate cutting through the upper FET structure to the oxide to form a first opening, filling the first opening with a first dielectric to form a deep dielectric plug, replacement metal gate (RMG) processing to form upper gate metal in the upper FET structure and executing post-RMG short gate cutting through the upper gate metal and adjacent to the first dielectric to reform a remainder of the upper gate metal proximal to the first dielectric into an L-shaped gate merge connection. Thus, the fabrication method provides for connection of respective gate metals of each of the upper FET device and the lower FET device.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of a stacked FET device in accordance with one or more embodiments of the present invention;

FIG. 2 is an enlarged side view of the portion of FIG. 1 identified by dashed line 2-2 in accordance with one or more embodiments of the present invention;

FIG. 3 is a flow diagram of a fabrication method of a stacked FET device in accordance with one or more embodiments of the present invention;

FIG. 4 is a side view of a stacked FET device structure in an initial stage of fabrication in accordance with one or more embodiments of the present invention;

FIG. 5 is a side view of a stacked FET device structure in a secondary stage of fabrication in accordance with one or more embodiments of the present invention;

FIG. 6 is a side view of a stacked FET device structure in a tertiary stage of fabrication in accordance with one or more embodiments of the present invention;

FIG. 7 is a side view of a stacked FET device structure in a fourth stage of fabrication in accordance with one or more embodiments of the present invention;

FIG. 8 is a side view of a stacked FET device structure in a fifth stage of fabrication in accordance with one or more embodiments of the present invention; and

FIG. 9 is a side view of a stacked FET device structure in a sixth stage of fabrication in accordance with one or more embodiments of the present invention.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the present invention, a gate merge connection assembly of a stacked field effect transistor (FET) device is provided. The gate merge connection assembly includes lower gate metal of a lower FET, upper gate metal of an upper FET and an L-shaped gate merge connection. The L-shaped gate merge connection includes a vertical section disposed in contact with the lower gate metal and extending upwardly through oxide vertically interposed between the lower and upper FETs and a horizontal section disposed in contact with the vertical section and extending horizontally to the upper gate metal. Thus, the stacked FET device provides for connection of respective gate metals of each of the upper FET device and the lower FET device.

In accordance with one or more additional and/or alternative embodiments of the present invention, the stacked FET device further includes a short dielectric plug extending along the upper gate metal and a deep dielectric plug extending along the short dielectric plug and the horizontal section to insulate the L-shaped gate merge connection.

In accordance with one or more additional and/or alternative embodiments of the present invention, the short dielectric plug extends to a plane of an uppermost surface of the horizontal section or lower which ensures contact between the short dielectric plug and the horizontal section.

In accordance with one or more additional and/or alternative embodiments of the present invention, the deep dielectric plug extends to a plane lower than a lowermost surface of the horizontal section which ensures insulation of the L-shaped gate merge connection.

In accordance with one or more additional and/or alternative embodiments of the present invention, each of the short dielectric plug and the deep dielectric plug includes at least one of a low-K dielectric material, a porous material and an airgap void to ensure isolation of the L-shaped gate merge connection.

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and an L-shaped gate merge connection. The lower FET includes lower gate metal surrounding semiconductor channels and a self-aligned contact (SAC) cap disposed over the lower gate metal. The upper FET includes upper gate metal surrounding semiconductor channels. The L-shaped gate merge connection includes a vertical section disposed in contact with the lower gate metal and extending upwardly through the oxide and a horizontal section disposed in contact with the vertical section and extending horizontally to the upper gate metal. Thus, the stacked FET device provides for connection of respective gate metals of each of the upper FET device and the lower FET device.

In accordance with one or more additional and/or alternative embodiments of the present invention, the oxide includes bonding oxide to insulate the lower FET from the upper FET.

In accordance with one or more additional and/or alternative embodiments of the present invention, the semiconductor channels are nanosheets to provide an efficient FET structure.

In accordance with one or more additional and/or alternative embodiments of the present invention, the stacked FET device further includes a short dielectric plug extending along the upper gate metal and a deep dielectric plug extending along the short dielectric plug and the horizontal section to insulate the L-shaped gate merge connection.

In accordance with one or more additional and/or alternative embodiments of the present invention, the short dielectric plug extends to a plane of an uppermost surface of the horizontal section or lower which ensures contact between the short dielectric plug and the horizontal section.

In accordance with one or more additional and/or alternative embodiments of the present invention, the deep dielectric plug extends to a plane lower than a lowermost surface of the horizontal section which ensures insulation of the L-shaped gate merge connection.

In accordance with one or more additional and/or alternative embodiments of the present invention, each of the short dielectric plug and the deep dielectric plug includes at least one of a low-K dielectric material, a porous material and an airgap void to ensure isolation of the L-shaped gate merge connection.

According to an aspect of the present invention, a fabrication method of a stacked field effect transistor (FET) device with a lower FET and an upper FET structure in a staggered formation and with oxide vertically interposed between the lower FET and the upper FET structure is provided. The fabrication method includes executing deep gate cutting through the upper FET structure to the oxide to form a first opening, filling the first opening with a first dielectric to form a deep dielectric plug, replacement metal gate (RMG) processing to form upper gate metal in the upper FET structure and executing post-RMG short gate cutting through the upper gate metal and adjacent to the first dielectric to reform a remainder of the upper gate metal proximal to the first dielectric into an L-shaped gate merge connection. Thus, the fabrication method provides for connection of respective gate metals of each of the upper FET device and the lower FET device.

In accordance with one or more additional and/or alternative embodiments of the present invention, the deep gate cutting is executed through epitaxy of the upper FET structure for compatibility with lithographic and complementary-metal-oxide-semiconductor (CMOS) processing.

In accordance with one or more additional and/or alternative embodiments of the present invention, the fabrication method further includes replacing epitaxy of the upper FET structure with a second dielectric, lithographically opening a second opening adjacent to the first dielectric to lower FET gate metal through the second dielectric, the oxide, and a lower FET self-aligned contact (SAC) cap and removing a remainder of the second dielectric to form a third opening in the upper FET structure for compatibility with lithographic and complementary-metal-oxide-semiconductor (CMOS) processing.

In accordance with one or more additional and/or alternative embodiments of the present invention, the RMG processing is executed in the upper FET structure to fill the second and third openings with the upper gate metal, the post-RMG short gate cutting is executed through the upper gate metal and adjacent to the first dielectric to form a fourth opening and the fabrication method further comprises filling the fourth opening with a third dielectric to form a short dielectric plug for compatibility with lithographic and complementary-metal-oxide-semiconductor (CMOS) processing.

In accordance with one or more additional and/or alternative embodiments of the present invention, the deep gate cutting dictates a depth of the deep dielectric plug and the post-RMG short gate cutting dictates a depth of the short dielectric plug to insulate the L-shaped gate merge connection.

In accordance with one or more additional and/or alternative embodiments of the present invention, each of the short dielectric plug and the deep dielectric plug includes at least one of a low-K dielectric material, a porous material and an airgap void to ensure isolation of the L-shaped gate merge connection.

In accordance with one or more additional and/or alternative embodiments of the present invention, the L-shaped gate merge connection includes a vertical section disposed in contact the lower gate metal of the lower FET and extending upwardly through the oxide and a horizontal section disposed in contact with the vertical section and extending horizontally to the upper gate metal to provide for electrical connection between the lower gate metal, the L-shaped gate merge connection and the upper gate metal.

In accordance with one or more additional and/or alternative embodiments of the present invention, the fabrication method further includes reforming the upper FET structure into an upper FET for compatibility with lithographic and complementary-metal-oxide-semiconductor (CMOS) processing.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, in a stacked FET, an upper FET device is stacked on top of a lower FET device and typically the upper FET device and the lower FET device are vertically aligned. In some cases, however, a stacked FET can have an offset or staggered formation in which the upper FET device is offset or staggered from the lower FET device. In these instances, a vertical center of the upper FET device is not located above the bottom FET device. For those stacked FETs having such an offset or staggered formation, it can be difficult to connect respective gate metals of each of the upper FET device and the lower FET device.

Turning now to an overview of the aspects of the disclosure, one or more embodiments of the disclosure address the above-described shortcomings of the prior art by providing a stacked FET with a top and bottom device gate connection that includes a vertical connection starting from the top of the bottom gate and a horizontal connection that merges to the bottom of the top device gate. A dielectric plug (i.e., a low-K dielectric material or air gap) may be disposed above the horizontal connection. A short dielectric plug can be disposed laterally adjacent to the top gate and can be disposed laterally adjacent to a deep dielectric plug. The deep dielectric plug can extend to a depth parallel to the bottom surface of the horizontal connection. The short dielectric plug can extend to a depth parallel to the top surface of the horizontal connection. The short dielectric plug can be one or more of a low-K dielectric material, a porous material and an airgap void to provide a capacitance benefit. One or more embodiments of the disclosure address the above-described shortcomings of the prior art by also providing that the top and bottom device gate connection can be formed by a combination of a gate cut first process executed before gate replacement and a post-replacement metal gate (post-RMG) gate cut last process. The gate cut first process dictates the depth of the deep dielectric plug and the gate cut last process dictates the depth of the short dielectric plug.

The above-described aspects of the disclosure address the shortcomings of the prior art by providing a stacked FET device including a lower FET, an upper FET disposed over the lower FET in a vertically mis-aligned formation, oxide vertically interposed between the lower FET and the upper FET and an L-shaped gate merge connection. The lower FET includes lower gate metal surrounding semiconductor channels and a self-aligned contact (SAC) cap disposed over the lower gate metal. The upper FET includes upper gate metal surrounding semiconductor channels. The L-shaped gate merge connection includes a vertical section disposed in contact with the lower gate metal and extending upwardly through the oxide and a horizontal section disposed in contact with the vertical section and extending horizontally to the upper gate metal.

In addition, the above-described aspects of the disclosure address the shortcomings of the prior art by also providing a fabrication method of a stacked FET device with a lower FET and an upper FET structure in a staggered formation and with oxide vertically interposed between the lower FET and the upper FET structure. The fabrication method includes executing deep gate cutting through the upper FET structure to the oxide to form a first opening, filling the first opening with a first dielectric to form a deep dielectric plug, replacement metal gate (RMG) processing to form upper gate metal in the upper FET structure and executing post-RMG short gate cutting through the upper gate metal and adjacent to the first dielectric to reform a remainder of the upper gate metal proximal to the first dielectric into an L-shaped gate merge connection.

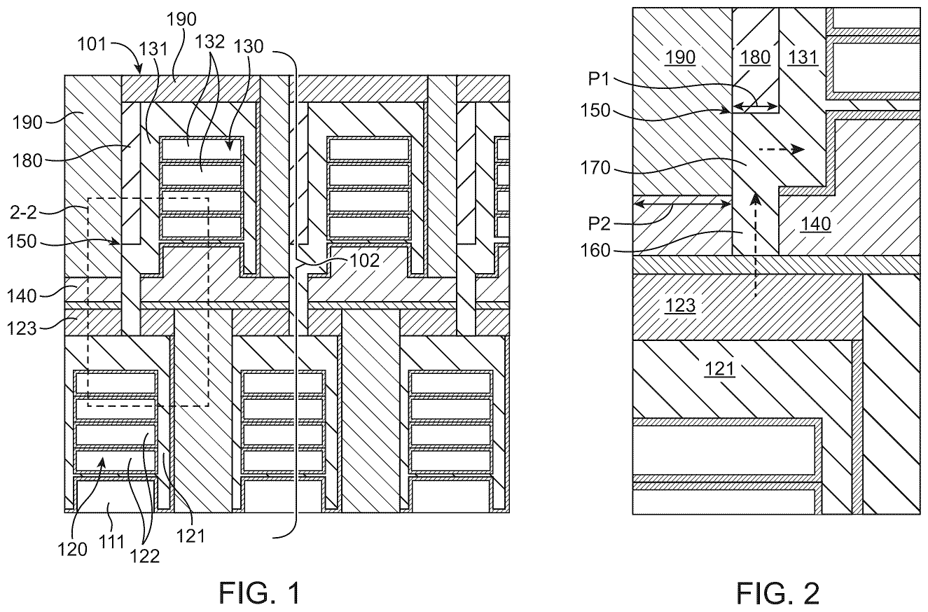

With reference to FIGS. 1 and 2, a stacked FET device 101 is provided and includes a substrate forming a pillar 111, a lower FET 120 disposed on the pillar 111, an upper FET 130 disposed over the lower FET 120 in a vertically mis-aligned formation 102, oxide 140 that is vertically interposed between the lower FET 120 and the upper FET 130 and an L-shaped gate merge connection 150. The lower FET 120 includes lower gate metal 121 surrounding semiconductor channels (i.e., nanosheet channels) 122 and an SAC cap 123 that is disposed over the lower gate metal 121. The upper FET 130 includes upper gate metal 131 surrounding semiconductor channels (i.e., nanosheet channels) 132. The oxide 140 can include or be provided as bonding oxide.

The L-shaped gate merge connection 150 can be formed of similar material as the lower gate metal 121 and the upper gate metal 131 and includes a vertical section 160 and a horizontal section 170. The vertical section 160 is disposed in electrical contact with the lower gate metal 121 and extends vertically upwardly through the SAC cap 123 and the oxide 140. The horizontal section 170 is disposed in electrical contact with an uppermost terminal end of the vertical section 160 and extends horizontally to make electrical contact with the upper gate metal 131.

The stacked FET device 101 further includes a short dielectric plug 180 and a deep dielectric plug 190. The short dielectric plug 180 extends vertically along a sidewall of the upper gate metal 131. A bottom-most edge of the short dielectric plug 180 extends to and terminates at a plane P1 of an uppermost surface of the horizontal section 170 or lower. The deep dielectric plug 190 extends vertically along and adjacent to the short dielectric plug 180 and a vertical face of the horizontal section 170. A bottom-most edge of the deep dielectric plug 190 extends to and terminates at a plane P2 that is lower than a lowermost surface of the horizontal section 170. It is to be understood that respective terminal depths of the short dielectric plug 180 and the deep dielectric plug 190 are effectively dictated by gate cutting operations to be described below. Respective materials of the short dielectric plug 180 and the deep dielectric plug 190 differ from one another and each of the short dielectric plug 180 and the deep dielectric plug 190 can include at least one of a low-K dielectric material, a porous material and an airgap void.

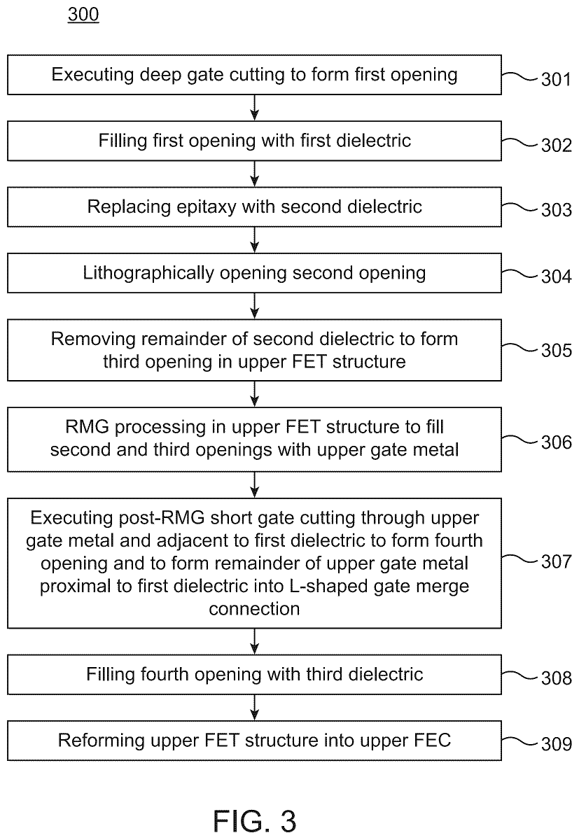

With continued reference to FIGS. 1 and 2 and with additional reference to FIG. 3, a fabrication method 300 of a stacked FET device, such as the stacked FET device 101 of FIGS. 1 and 2, is provided. That is, the stacked FET device includes a lower FET and an upper FET structure in a staggered formation and oxide vertically interposed between the lower FET and the upper FET structure.

As shown in FIG. 3, the fabrication method 300 includes executing deep gate cutting through epitaxy of the upper FET structure to the oxide to form a first opening (block 301), filling the first opening with a first dielectric (block 302) and replacing the epitaxy with a second dielectric (block 303). The fabrication method 300 further includes lithographically opening a second opening adjacent to the first dielectric to lower FET gate metal through the second dielectric, the oxide and an SAC cap of the lower FET (block 304), removing a remainder of the second dielectric to form a third opening in the upper FET structure (block 305). In addition, the fabrication method 300 includes RMG processing in the upper FET structure to fill the second and third openings with upper gate metal (block 306) and executing post-RMG short gate cutting through the upper gate metal and adjacent to the first dielectric to form a fourth opening and to form a remainder of the upper gate metal proximal to the first dielectric into an L-shaped gate merge connection (block 307). The fabrication method 300 also includes filling the fourth opening with a third dielectric (block 308) and reforming the upper FET structure into an upper FET (block 309) (i.e., by completing the formation of the upper FET, such as by forming an SAC cap on the upper FET).

As noted above, the L-shaped gate merge connection can be provided as the L-shaped gate merge connection 150 of FIGS. 1 and 2 and can include the vertical section 160 and the horizontal section 170 of FIGS. 1 and 2.

The deep gate cutting of block 301 effectively dictates a depth of the deep dielectric plug (i.e., the deep dielectric plug 190 of FIGS. 1 and 2) and the post-RMG short gate cutting of block 307 effectively dictates a depth of the short dielectric plug (i.e., the short dielectric plug 180 of FIGS. 1 and 2), where the short dielectric plug and the deep dielectric plug differ from another and where each of the short dielectric plug and the deep dielectric plug includes at least one of a low-K dielectric material, a porous material and an airgap void. Since the deep gate cutting of block 301 effectively dictates the depth of the deep dielectric plug and the post-RMG short gate cutting of block 307 effectively dictates the depth of the short dielectric plug, the respective depths of the short dielectric plug and the deep dielectric plug can be variable. As such, subject to capacitance requirements and/or limitations, at least the horizontal section 170 of FIGS. 1 and 2 can be made thicker or thinner.

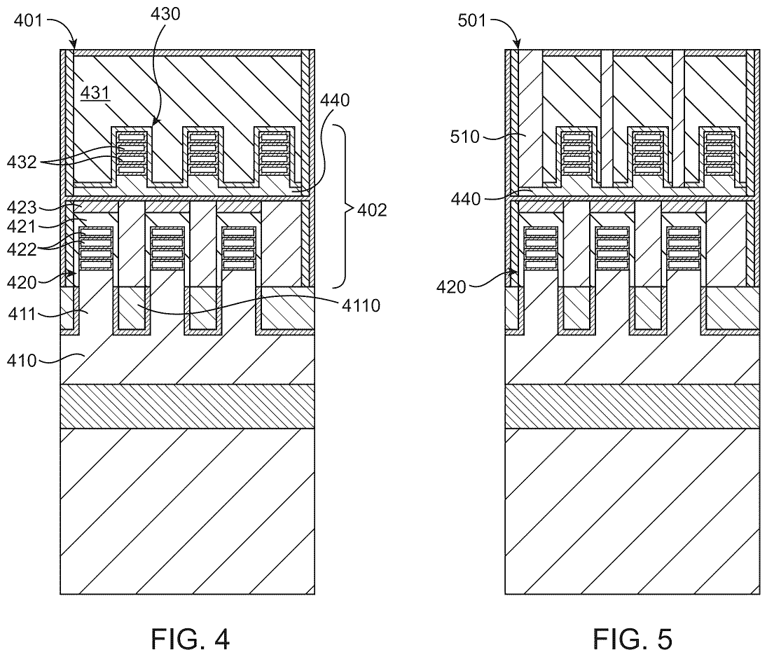

With continued reference to FIGS. 1-3 and with additional reference to FIGS. 4-9, the fabrication method 300 of FIG. 3 is graphically illustrated in each of the side views of FIGS. 4-9.

As shown in FIG. 4, a stacked FET device structure 401 is provided at an initial fabrication stage. The stacked FET device structure 401 includes a substrate 410 forming a pillar 411 with shallow trench isolation (SDI) 4110 between the pillar 411 and adjacent pillars, a lower FET 420 disposed on the pillar 411, an upper FET structure 430 disposed over the lower FET 420 in a vertically mis-aligned formation 402 (i.e., over the STI 4110) and oxide 440 that is vertically interposed between the lower FET 420 and the upper FET structure 430. The lower FET 420 includes lower gate metal 421 surrounding semiconductor channels (i.e., nanosheet channels) 422 and an SAC cap 423 that is disposed over the lower gate metal 421. The upper FET structure 430 includes epitaxy 431 and channels 432. The oxide 440 can include or be provided as bonding oxide.

As shown in FIG. 5, a stacked FET device structure 501 is shown in a secondary fabrication stage following a pre-RMG deep gate cut and a fill process executed with respect to the stacked FET device structure 401 of FIG. 4. The pre-RMG deep gate cut opens a first opening through the epitaxy 431 of FIG. 4. The fill process can be a chemical vapor deposition (CVD) process and forms a deep dielectric plug 510 in the first opening. A depth of the pre-RMG gate cut dictates a terminal depth of the deep dielectric plug 510, which in the case of FIG. 5, is at a plane that is lower than an uppermost plane of the oxide 440 over the lower FET 420. The deep dielectric plug 510 can include an oxide or another suitable dielectric material (e.g., a low-K dielectric material, a porous material and an airgap void).

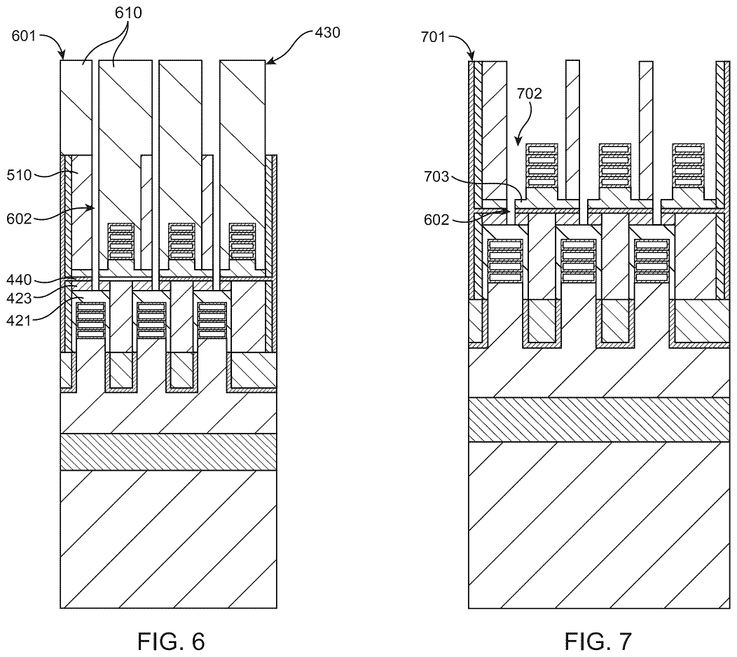

As shown in FIG. 6, a stacked FET device structure 601 is shown in a tertiary fabrication stage following removal of the epitaxy 431 of FIG. 4, a high-K dielectric deposition and a lithographic processing operation executed with respect to the stacked FET device structure 501 of FIG. 5. As a result of the removal of the epitaxy 431 of FIG. 4 and the high-K deposition, the upper FET structure 430 includes high-K dielectric material 610. The lithographic processing can be done in multiple steps and eventually forms a second opening 602. The second opening 602 is adjacent to the deep dielectric plug 510 and extends through the high-K dielectric material 610, through the oxide 440, through the SAC cap 423 and to the lower gate metal 421.

As shown in FIG. 7, a stacked FET device structure 701 is shown in a fourth fabrication stage following removal of a remainder of the high-K dielectric material 610 of FIG. 6 executed with respect to the stacked FET device structure 601 of FIG. 6. The removal of the remainder of the high-K dielectric material 610 results in the formation of a third opening 702 adjacent to the second opening 602. At this point, the L-shaped gate merge connection 150 of FIGS. 1 and 2 begins to form and can be observed in the corner 703.

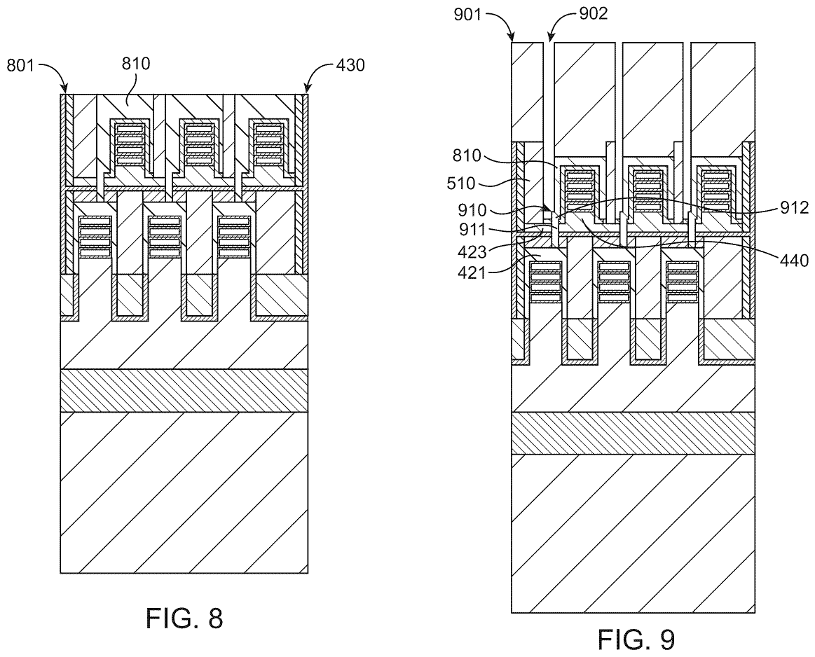

As shown in FIG. 8, a stacked FET device structure 801 is shown in a fifth fabrication stage following RMG processing and chemical mechanical polishing (CMP) executed with respect to the stacked FET device structure 701 of FIG. 7. The RMG processing results in the provision of upper gate metal 810 in the second opening 602 of FIG. 6 and in the third opening 702 of FIG. 7 and in the provision of the upper gate metal 810 surrounding the channels 432 of FIG. 4 in the upper FET structure 430.

As shown in FIG. 9, a stacked FET device structure 901 is shown in a sixth fabrication stage following additional lithographic processing executed with respect to the stacked FET device structure 801 of FIG. 8. The lithographic processing is an execution of a post-RMG short gate cut through the upper gate metal 810 and adjacent to the deep dielectric plug 510 to form a fourth opening 902 and to form a remainder of the upper gate metal 810 at a location that is proximal to the deep dielectric plug 510 into an L-shaped gate merge connection 910. The L-shaped gate merge connection 910 includes a vertical section 911 and a horizontal section 912. The vertical section 911 is disposed in electrical contact with the lower gate metal 421 and extends vertically upwardly through the SAC cap 423 and the oxide 440. The horizontal section 912 is disposed in electrical contact with an uppermost terminal end of the vertical section 911 and extends horizontally to make electrical contact with the upper gate metal 810.

A depth of the post-RMG gate cut dictates a terminal depth of the short dielectric plug (see below) and dictates a plane of the uppermost surface of the horizontal section 912. The depth can be variable based on capacitance requirements and/or limitations.

The stacked FET device 101 can subsequently be obtained following a fill operation that fills the fourth opening 902 of FIG. 9 with dielectric material and subsequent processing executed with respect to the stacked FET device structure 901 of FIG. 9. The dielectric material filling the fourth opening forms the short dielectric plug 180 of FIGS. 1 and 2. The subsequent processing can form an SAC cap 123 (see FIG. 1) on the upper gate metal 131 of the upper FET 130 of FIGS. 1 and 2.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A gate merge connection assembly of a stacked field effect transistor (FET) device, the gate merge connection assembly comprising:
lower gate metal of a lower FET;
upper gate metal of an upper FET; and
an L-shaped gate merge connection comprising:
a vertical section disposed in contact with the lower gate metal and extending upwardly through oxide vertically interposed between the lower and upper FETs; and
a horizontal section disposed in contact with the vertical section and extending horizontally to the upper gate metal.

2. The stacked FET device according to claim 1, further comprising:
a short dielectric plug extending along the upper gate metal; and
a deep dielectric plug extending along the short dielectric plug and the horizontal section.

3. The stacked FET device according to claim 2, wherein the short dielectric plug extends to a plane of an uppermost surface of the horizontal section or lower.

4. The stacked FET device according to claim 2, wherein the deep dielectric plug extends to a plane lower than a lowermost surface of the horizontal section.

5. The stacked FET device according to claim 2, wherein each of the short dielectric plug and the deep dielectric plug comprises at least one of a low-K dielectric material, a porous material and an airgap void.

6. A stacked field effect transistor (FET) device, comprising:
a lower FET, an upper FET disposed over the lower FET in a vertically mis-aligned formation, and oxide vertically interposed between the lower FET and the upper FET,
wherein the lower FET comprises lower gate metal surrounding semiconductor channels and a self-aligned contact (SAC) cap disposed over the lower gate metal, and wherein the upper FET comprises upper gate metal surrounding semiconductor channels; and
an L-shaped gate merge connection comprising:
a vertical section disposed in contact with the lower gate metal and extending upwardly through the oxide; and
a horizontal section disposed in contact with the vertical section and extending horizontally to the upper gate metal.

7. The stacked FET device according to claim 6, wherein the oxide comprises bonding oxide.

8. The stacked FET device according to claim 6, wherein the semiconductor channels are nanosheets.

9. The stacked FET device according to claim 6, further comprising:
a short dielectric plug extending along the upper gate metal; and
a deep dielectric plug extending along the short dielectric plug and the horizontal section.

10. The stacked FET device according to claim 9, wherein the short dielectric plug extends to a plane of an uppermost surface of the horizontal section or lower.

11. The stacked FET device according to claim 9, wherein the deep dielectric plug extends to a plane lower than a lowermost surface of the horizontal section.

12. The stacked FET device according to claim 9, wherein each of the short dielectric plug and the deep dielectric plug comprises at least one of a low-K dielectric material, a porous material and an airgap void.

13. A fabrication method of a stacked field effect transistor (FET) device with a lower FET and an upper FET structure in a staggered formation and with oxide vertically interposed between the lower FET and the upper FET structure, the fabrication method comprising:
executing deep gate cutting through the upper FET structure to the oxide to form a first opening;
filling the first opening with a first dielectric to form a deep dielectric plug;
replacement metal gate (RMG) processing to form upper gate metal in the upper FET structure; and
executing post-RMG short gate cutting through the upper gate metal and adjacent to the first dielectric to reform a remainder of the upper gate metal proximal to the first dielectric into an L-shaped gate merge connection.

14. The fabrication method according to claim 13, wherein the deep gate cutting is executed through epitaxy of the upper FET structure.

15. The fabrication method according to claim 13, further comprising:
replacing epitaxy of the upper FET structure with a second dielectric;
lithographically opening a second opening adjacent to the first dielectric to lower FET gate metal through the second dielectric, the oxide, and a lower FET self-aligned contact (SAC) cap; and
removing a remainder of the second dielectric to form a third opening in the upper FET structure.

16. The fabrication method according to claim 15, wherein:
the RMG processing is executed in the upper FET structure to fill the second and third openings with the upper gate metal,
the post-RMG short gate cutting is executed through the upper gate metal and adjacent to the first dielectric to form a fourth opening, and
the fabrication method further comprises filling the fourth opening with a third dielectric to form a short dielectric plug.

17. The fabrication method according to claim 16, wherein the deep gate cutting dictates a depth of the deep dielectric plug and the post-RMG short gate cutting dictates a depth of the short dielectric plug.

18. The fabrication method according to claim 16, wherein each of the short dielectric plug and the deep dielectric plug comprises at least one of a low-K dielectric material, a porous material and an airgap void.

19. The fabrication method according to claim 13, wherein the L-shaped gate merge connection comprises:
a vertical section disposed in contact the lower gate metal of the lower FET and extending upwardly through the oxide; and
a horizontal section disposed in contact with the vertical section and extending horizontally to the upper gate metal.

20. The fabrication method according to claim 13, further comprising reforming the upper FET structure into an upper FET.
